(19) United States
(12) Patent Application Publication
(10) Pub. No.: US 2010/0190315 A1
(43) Pub. Date: Jul. 29, 2010

(54) METHOD OF MANUFACTURING SEMICONDUCTOR MEMORY DEVICE

(76) Inventors: Hack Seob SHIN, Gyeonggi-do (KR); Kyoung Hwan Park, Seoul (KR)

Correspondence Address: IP & T Law Firm PLC, 7700 Little River Turnpike, Suite 207, Annandale, VA, 22003, US

(21) Appl. No.: 12/613,045

(22) Filed: Nov. 5, 2009

(30) Foreign Application Priority Data
Jan. 29, 2009 (KR) 10-2009-0006806

(51) Int. Cl. H01L 21/8239; H01L 21/762

(52) U.S. Cl. 438/396; 438/424; 438/594; 438/591; 257/E21.645; 257/E21.409; 257/E21.546

(57) ABSTRACT

There is provided a method of manufacturing a semiconductor memory device. According to the method, a tunnel insulating layer and a charge trap layer are formed in a cell region of a semiconductor substrate defining the cell region and a peripheral region. A gate insulation layer and a first conductive layer are formed over the semiconductor substrate of the peripheral region. A blocking insulating layer is formed on the charge trap layer of the cell region and the first conductive layer of the peripheral region. A second conductive layer is formed over the entire surface including the blocking insulating layer, thereby forming a capacitor having a stack structure of the first conductive layer, the blocking insulating layer, and the second conductive layer.

### CROSS-REFERENCE TO RELATED APPLICATION

Priority to Korean patent application number 10-2009-0006806 filed on Jan. 29, 2009, the entire disclosure of which is incorporated by reference herein, is claimed.

### BACKGROUND

An embodiment relates to a method of manufacturing a semiconductor memory device and, more particularly, to a method of manufacturing a semiconductor memory device, which is capable of forming a capacitor in a semiconductor memory device having a SONOS structure.

The data storage capacity of a semiconductor memory device depends on the degree of integration indicating the number of memory cells per unit area. In general, a semiconductor memory device includes numerous memory cells which are interconnected circuit components. For example, in DRAM, one memory cell chiefly consists of one transistor and one capacitor.

According to research on a high-density integrated circuit with low consumption power and a high-speed operation, technologies using a silicon on insulator (SOI) substrate in the next-generation semiconductor memory device are being developed. The semiconductor memory device using the SOT substrate can be fabricated using a relatively simple process, and it enables a small isolation gap between NMOS and CMOS because of the advantage in terms of isolation for a unit element, thereby enabling a high density. Accordingly, the technologies using the SOI substrate are for the most part used to form memory devices of 100 nm or less. Silicon/oxide/nitride/oxide/silicon (SONOS) and metal/Al₂O₃/nitride/oxide/silicon (MANOS) memory devices are two of the emerging memory devices.

The SONOS or MANOS memory device typically has a structure, including a silicon layer configured to have a channel region formed therein, an oxide layer configured to form a tunnel layer, a nitride layer used as a charge trap layer, an oxide layer used as a blocking layer, and a polysilicon layer used as a control gate. The above layers are chiefly referred as the elements of the SONOS or MANOS structure.

The SONOS and MANOS memory devices can have an oxide layer of a thin thickness as compared with flash memory devices because charges are stored in the trap of a deep level which is spatially isolated within the trap layer. Accordingly, the SONOS and MANOS memory devices can operate even at a low gate voltage, and they are advantageous in terms of a high integration.

The SONOS and MANOS memory devices have to implement a capacitor using the gate insulation layer of a high voltage region when forming the capacitor in a peripheral region because they do not use the dielectric layer of an ONO structure, unlike flash memory devices having a floating gate. Accordingly, the SONOS and MANOS memory devices are problematic in that the capacity of a capacitor is low and the size of a capacitor is great because of an increase in the equivalent oxide thickness (EOT).

### BRIEF SUMMARY

An embodiment relates to a method of manufacturing a semiconductor memory device, which is capable of decreasing the size of a capacitor and increasing the capacity of a capacitor by forming a dielectric layer for the capacitor of a peripheral region using a blocking insulating layer formed in the cell region of a charge trap-type device.

A method of manufacturing a semiconductor memory device according to an embodiment comprises forming a tunnel insulating layer and a charge trap layer in a cell region of a semiconductor substrate defining the cell region and a peripheral region, forming a gate insulation layer and a first conductive layer over the semiconductor substrate of the peripheral region, forming a blocking insulating layer on the charge trap layer of the cell region and the first conductive layer of the peripheral region, and forming a second conductive layer over an entire surface including the blocking insulating layer, thereby forming a capacitor having a stack structure of the first conductive layer, the blocking insulating layer, and the second conductive layer.

The peripheral region includes a capacitor region and a transistor region.

Formation of the tunnel insulating layer and the charge trap layer comprises sequentially forming the tunnel insulating layer and the charge trap layer over the semiconductor substrate, forming a hard mask layer on the charge trap layer, forming trenches for isolation by etching the hard mask layer, the charge trap layer, the tunnel insulating layer, and the semiconductor substrate, filling the trenches with an insulating material to form isolation layers, and removing the hard mask layer, the charge trap layer, and the tunnel insulating layer formed in the peripheral region.

The method further comprises forming a first mask pattern on the hard mask layer of the cell region before removing the hard mask layer, the charge trap layer, and the tunnel insulating layer formed in the peripheral region.

The method further comprises removing the first mask pattern of the cell region after removing the hard mask layer, the charge trap layer, and the tunnel insulating layer formed in the peripheral region.

Formation of the gate insulation layer and the first conductive layer comprises: forming the gate insulation layer and the first conductive layer over the hard mask layer of the cell region and over the semiconductor substrate of the peripheral region, including the isolation layers, forming a second mask pattern on the first conductive layer formed in the peripheral region, and removing the hard mask layer and a top portion of the isolation layers of the cell region to expose the charge trap layer.

The method further comprises removing the second mask pattern of the peripheral region after removing the hard mask layer and the top portion of the isolation layers of the cell region.

The blocking insulating layer is made of any one material selected from the group consisting of Al₂O₃, Y₂O₃, La₂O₃, Ta₂O₅, TiO₂, HfO₂, and ZrO₂. The blocking insulating layer is formed of a high-k layer, and the high-k layer has a dielectric constant of 9 to 25. Alternatively, the blocking insulating layer can be formed of a mixture including two kinds of materials selected from among Al₂O₃, Y₂O₃, La₂O₃, Ta₂O₅, TiO₂, HfO₂, and ZrO₂.

The method further comprises exposing the first conductive layer by etching part of the blocking insulating layer formed in the transistor region of peripheral region after forming the blocking insulating layer.

The first and second conductive layers are formed of a polysilicon layer.

The method further comprises etching the second conductive layer and the blocking insulating layer formed at a boundary of the cell region and the peripheral region after forming the second conductive layer.

The method further comprises simultaneously etching the second conductive layer and the blocking insulating layer formed at a boundary of the capacitor region and the transistor region in the peripheral region when the etching the second conductive layer and the blocking insulating layer formed at a boundary of the cell region and the peripheral region.

After forming the second conductive layer, the method further comprises forming a contact hole exposing the first conductive layer by etching the second conductive layer and the blocking insulating layer formed in the peripheral region, forming a lower contact plug coupled to the first conductive layer, and forming upper contact plugs coupled to the second conductive layer.

A method of manufacturing a semiconductor memory device according to other embodiment comprises forming a tunnel insulating layer, a charge trap layer, and a hard mask layer over a semiconductor substrate, forming trenches for isolation by etching the hard mask layer, the charge trap layer, the tunnel insulating layer, and the semiconductor substrate, filling the trenches with an insulating material to form isolation layers, removing the hard mask layer, the charge trap layer, and the tunnel insulating layer formed in a capacitor region of the semiconductor substrate, forming a gate insulation layer and a first conductive layer over the semiconductor substrate of the capacitor region, removing the hard mask layer formed in a cell region of the semiconductor substrate, and forming a blocking insulating layer and a second conductive layer over an entire surface which includes the cell region and the capacitor region.

### BRIEF DESCRIPTION OF THE DRAWINGS

FIGS. 1A to 1H are cross-sectional views illustrating a method of manufacturing a semiconductor memory device according to an embodiment.

### DESCRIPTION OF EMBODIMENT

Hereinafter, an embodiment of the present disclosure will be described in detail with reference to the accompanying drawings. The drawing figures are provided to allow those having ordinary skill in the art to understand the scope of the embodiment of the disclosure.

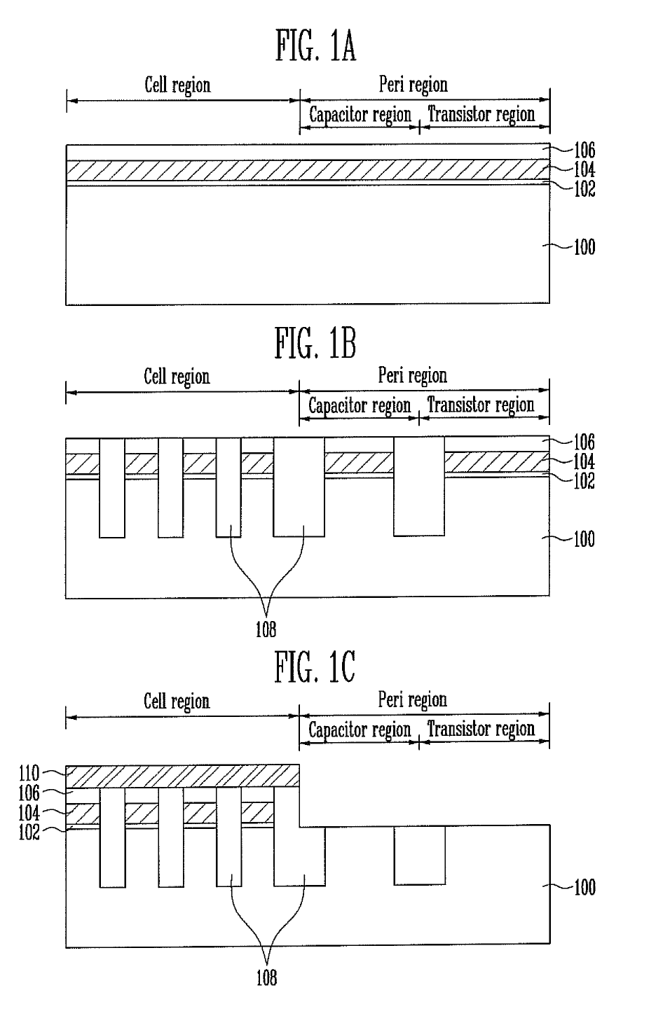

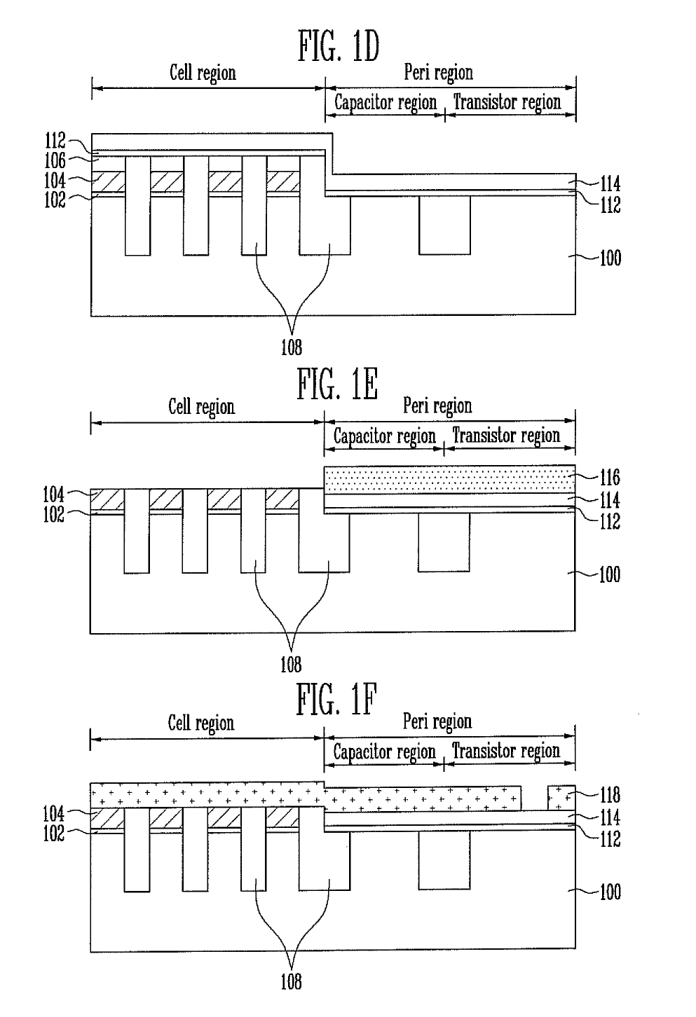

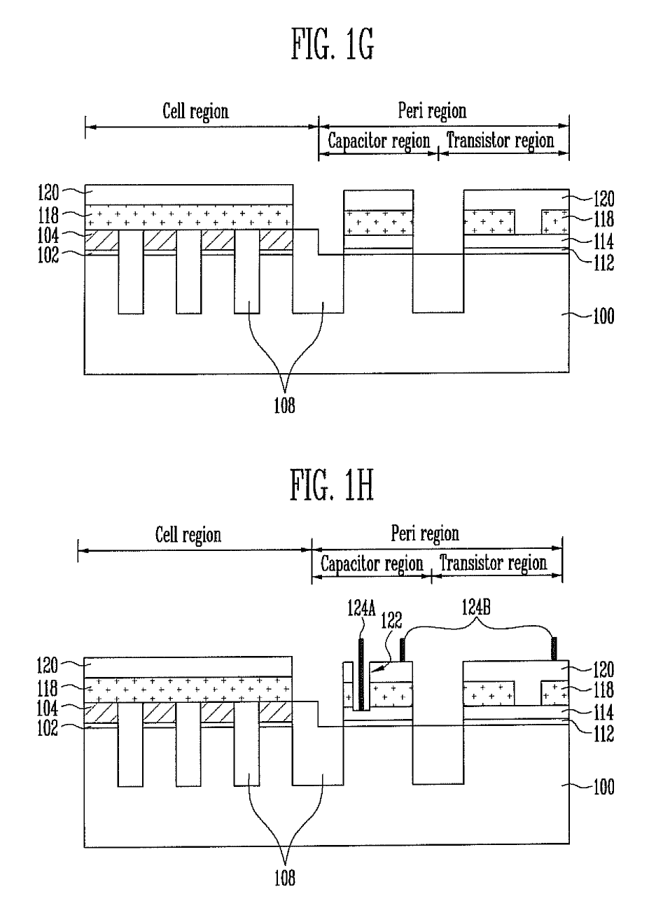

FIGS. 1A to 1H are cross-sectional views illustrating a method of manufacturing a semiconductor memory device according to an embodiment.

Referring to FIG. 1A, there is provided a semiconductor substrate 100 defining a cell region and a peripheral region. The peripheral region includes a capacitor region and a transistor region.

A tunnel insulating layer 102 and a charge trap layer 104 are sequentially stacked over the semiconductor substrate 100. The tunnel insulating layer 102 preferably is formed of an oxide layer, and the charge trap layer 104 preferably is formed of a nitride layer.

A hard mask layer 106 is formed on the charge trap layer 104. The hard mask layer 106 is used as a mask for isolation.

Referring to FIG. 1B, a first etch process is performed to pattern the hard mask layer 106. Isolation regions of the semiconductor substrate 100 are exposed by etching the exposed charge trap layer 104 and the tunnel insulating layer 102. The exposed isolation regions are etched to a certain depth to thereby form trenches for isolation in the respective isolation regions. The trenches for isolation are filled with an insulating layer to thereby form isolation layers 108. The isolation layers 108 preferably are formed of an oxide layer.

Next, a second etch process preferably is performed to expose the hard mask layer 106.

Referring to FIG. 1C, a mask layer is formed over the entire surface that includes the hard mask layer 106 and the isolation layers 108. The mask layer is patterned to form a first mask pattern 110 only in the cell region of the semiconductor substrate 100.

Next, a third etch process using the first mask pattern 110 is performed to etch the hard mask layer 106, the charge trap layer 104, the tunnel insulating layer 102, and part of the isolation layers 108, of the peripheral region. Here, a top portion of the isolation layer 108 preferably is etched as high as a top portion of the semiconductor substrate 100 of the peripheral region.

Referring to FIG. 1D, a first cleaning process is performed to remove the first mask pattern 110. Next, a gate insulation layer 112 and a first conductive layer 114 are formed over the entire surface that includes the hard mask layer 106, the isolation layer 108, and the semiconductor substrate 100. The gate insulation layer 112 preferably is formed of an oxide layer. The first conductive layer 114 is used as the lower electrode of a capacitor and the gate conductive layer of a transistor. The first conductive layer 114 preferably is formed of a polysilicon layer.

Referring to FIG. 1E, a mask layer is formed over the entire surface including the first conductive layer 114. The mask layer is patterned to thereby form a second mask pattern 116 only in the peripheral region of the semiconductor substrate 100.

A fourth etch process using the first mask pattern 116 is performed to etch the first conductive layer 114, the gate insulation layer 112, the hard mask layer 106, and a top portion of the isolation layers 108, of the cell region.

Referring to FIG. 1F, a second cleaning process is performed to remove the second mask pattern 116. Next, a blocking insulating layer 118 is formed over the entire surface that includes the charge trap layer 104 and the isolation layer 108 of the cell region and the first conductive layer 114 of the peripheral region. The blocking insulating layer 118 is formed of a high dielectric (high-k) layer and preferably is made of any one material selected from the group consisting of Al₂O₃, Y₂O₃, La₂O₃, Ta₂O₅, TiO₂, HfO₂, and ZrO₂. The blocking insulating layer 118 preferably is made of any one material selected from the group consisting of Al₂O₃, Y₂O₃, HfO₂, and ZrO₂ (which have a dielectric constant of 9 to 25) with the dielectric constant taken into consideration. Alternatively, the blocking insulating layer 118 can be made of any one mixture selected from among a number of mixtures (e.g., HfOxAlyOz, ZrOxAlyOz, and LaOxAlyOz), each having a composition in which two kinds of materials selected from the group consisting of Al₂O₃, Y₂O₃, La₂O₃, Ta₂O₅, TiO₂, HfO₂, and ZrO₂ are adequately mixed. The blocking insulating layer 118 preferably is made of HfOxAlyOz. Here, x, y, and z are natural numbers and each refer to a composition ratio of materials constituting the mixture.

Next, a fifth etch process is performed to etch part of the blocking insulating layer 118 formed in the transistor region of the peripheral region, thereby exposing part of the first conductive layer 114.

Referring to FIG. 1G, a second conductive layer 120 is formed over the entire surface including the blocking insulating layer 118. The second conductive layer 120 is used as a gate conductive layer in the cell region and in the transistor region of the peripheral region, and is used as an upper electrode layer in a capacitor region of the peripheral region. The second conductive layer 120 preferably is formed of a polysilicon layer. The second conductive layer 120 of the transistor region is electrically coupled to the first conductive layer 114.

Next, a sixth etch process is performed to remove the second conductive layer 120, the blocking insulating layer 118, the first conductive layer 114, and the gate insulation layer 112, which are formed at the boundary of the cell region and the peripheral region. The sixth etch process also removes the second conductive layer 120, the blocking insulating layer 118, the first conductive layer 114, and the gate insulation layer 112, which are formed at the boundary of the transistor region and the capacitor region of the peripheral region.

Referring to FIG. 1H, a seventh etch process is performed to form a contact hole 122 that exposes part of the first conductive layer 114 of the capacitor region. Next, a lower contact plug 124A coupled to the first conductive layer 114 is formed. More preferably, after forming the contact hole 122, an insulating layer is formed on the sidewalls of the contact hole 122 such that the subsequent lower contact plug 124A is electrically isolated from the blocking insulating layer 118 and the second conductive layer 120. Next, upper contact plugs 124B coupled to the second conductive layer 120 of the capacitor region and the second conductive layer 120 of the transistor region are formed.

As described above, when fabricating the semiconductor memory device having the SONOS structure, the blocking insulating layer formed of a high-k layer is used as the dielectric layer of a capacitor. Accordingly, the capacity of the capacitor can be increased and the size of the capacitor can be reduced.

Although, in the embodiment of this disclosure, the SONOS memory device has been described as an example, the embodiment of this disclosure can be applied to a MANOS memory device or a TANOS memory device.

Furthermore, the dielectric layer for a capacitor of the peripheral region is formed using the blocking insulating layer formed in the cell region of a charge trap-type device. Accordingly, the capacity of the capacitor can be increased and the size of the capacitor can be reduced.

What is claimed is:

1. A method of manufacturing a semiconductor memory device, comprising:
forming a tunnel insulating layer and a charge trap layer in a cell region of a semiconductor substrate defining the cell region and a peripheral region;
forming a gate insulation layer and a first conductive layer over the semiconductor substrate of the peripheral region;
forming a blocking insulating layer on the charge trap layer of the cell region and the first conductive layer of the peripheral region; and
forming a second conductive layer over an entire surface including the blocking insulating layer, thereby forming a capacitor having a stack structure of the first conductive layer, the blocking insulating layer, and the second conductive layer.

2. The method of claim 1, wherein the peripheral region includes a capacitor region and a transistor region.

3. The method of claim 1, wherein forming the tunnel insulating layer and the charge trap layer comprises:
sequentially forming the tunnel insulating layer and the charge trap layer over the semiconductor substrate;
forming a hard mask layer on the charge trap layer;
forming trenches for isolation by etching the hard mask layer, the charge trap layer, the tunnel insulating layer, and the semiconductor substrate;
filling the trenches with an insulating material to form isolation layers; and
removing the hard mask layer, the charge trap layer, and the tunnel insulating layer formed in the peripheral region.

4. The method of claim 3, further comprising:
forming a first mask pattern on the hard mask layer of the cell region before removing the hard mask layer, the charge trap layer, and the tunnel insulating layer formed in the peripheral region.

5. The method of claim 4, further comprising:
removing the first mask pattern of the cell region after removing the hard mask layer, the charge trap layer, and the tunnel insulating layer formed in the peripheral region.

6. The method of claim 3, wherein forming the gate insulation layer and the first conductive layer comprises:
forming the gate insulation layer and the first conductive layer over the hard mask layer of the cell region and over the semiconductor substrate of the peripheral region, including the isolation layers;
forming a second mask pattern on the first conductive layer formed in the peripheral region; and
removing the hard mask layer and a top portion of the isolation layers of the cell region to expose the charge trap layer.

7. The method of claim 6, further comprising:
removing the second mask pattern of the peripheral region after removing the hard mask layer and the top portion of the isolation layers of the cell region.

8. The method of claim 1, wherein the blocking insulating layer is made of any one material selected from the group consisting of Al₂O₃, Y₂O₃, La₂O₃, Ta₂O₅, TiO₂, HfO₂, and ZrO₂.

9. The method of claim 1, wherein the blocking insulating layer is formed of a high-k layer, wherein the high-k layer has a dielectric constant of 9 to 25.

10. The method of claim 1, wherein the blocking insulating layer is formed of a mixture including two kinds of materials selected from among Al₂O₃, Y₂O₃, La₂O₃, Ta₂O₅, TiO₂, HfO₂, and ZrO₂.

11. The method of claim 2, further comprising:
exposing the first conductive layer by etching part of the blocking insulating layer formed in the transistor region of the peripheral region after forming the blocking insulating layer.

12. The method of claim 1, wherein the first and second conductive layers are formed of a polysilicon layer.

13. The method of claim 1, further comprising:
etching the second conductive layer and the blocking insulating layer formed at a boundary of the cell region and the peripheral region after forming the second conductive layer.

14. The method of claim 13, further comprising:
simultaneously etching the second conductive layer and the blocking insulating layer formed at a boundary of the capacitor region and the transistor region in the peripheral region when the etching the second conductive layer and the blocking insulating layer formed at a boundary of the cell region and the peripheral region.

15. The method of claim 1, further comprising after forming the second conductive layer:
forming a contact hole exposing the first conductive layer by etching the second conductive layer and the blocking insulating layer formed in the peripheral region after forming the second conductive layer;
forming a lower contact plug coupled to the first conductive layer; and
forming upper contact plugs coupled to the second conductive layer.

16. A method of manufacturing a semiconductor memory device, comprising:
forming a tunnel insulating layer, a charge trap layer, and a hard mask layer over a semiconductor substrate;
forming trenches for isolation by etching the hard mask layer, the charge trap layer, the tunnel insulating layer, and the semiconductor substrate;
filling the trenches with an insulating material to form isolation layers;
removing the hard mask layer, the charge trap layer, and the tunnel insulating layer formed in a capacitor region of the semiconductor substrate;
forming a gate insulation layer and a first conductive layer over the semiconductor substrate of the capacitor region;
removing the hard mask layer formed in a cell region of the semiconductor substrate; and
forming a blocking insulating layer and a second conductive layer over an entire surface which includes the cell region and the capacitor region.

17. The method of claim 16, further comprising:
removing the second conductive layer and the blocking insulating layer formed at a boundary of the cell region and the capacitor region after forming the second conductive layer.

18. The method of claim 16, wherein the blocking insulating layer is made of any one material selected from the group consisting of Al₂O₃, Y₂O₃, La₂O₃, Ta₂O₅, TiO₂, HfO₂, and ZrO₂.

19. The method of claim 16, wherein the blocking insulating layer is formed of a high-k layer, wherein the high-k layer has a dielectric constant of 9 to 25.

20. The method of claim 16, wherein the blocking insulating layer is formed of a mixture including two kinds of materials selected from among Al₂O₃, Y₂O₃, La₂O₃, Ta₂O₅, TiO₂, HfO₂, and ZrO₂.
